(19) United States
(12) Patent Application Publication
(10) Pub. No.: US 2026/0354187 A1
(43) Pub. Date: Nov. 5, 2026

(54) Cold Plate With Lateral Compliance Including Compliant Ribs

(71) Applicant: Eridu Corporation, Saratoga, CA (US)

(72) Inventors: Donald Arthur Ice, Milpitas, CA (US); Ting-Kuang Ch, Saratoga, CA (US)

(73) Assignee: Eridu Corporation, Saratoga, CA (US)

(21) Appl. No.: 19/644,843

(22) Filed: Apr. 10, 2026

Related U.S. Application Data
(60) Provisional application No. 63/786,488, filed on Apr. 10, 2025.

(51) Int. Cl. H10W 40/47; H10W 40/20

(52) U.S. Cl. CPC H10W 40/47; H10W 40/242

(57) ABSTRACT

Some implementations described herein provide a cold plate for semiconductor cooling that incorporates structural compliance to accommodate differential thermal expansion between the cold plate and adjacent semiconductor chips. For example, the apparatus includes a cold plate comprising a first portion with a plurality of thermally conductive portions, such as pillars, wherein the pillars are spaced from one another at their first ends adjacent the chip surface. The cold plate is configured to absorb thermally induced stress in both the X and Y directions parallel to the chip surface, while maintaining rigidity in the Z direction perpendicular to the chip surface. The second ends of the pillars, in one example, merge to form a second portion of the cold plate, facilitating heat transfer away from the chip. In some aspects, the pillars may be solid or hollow. If hollow, channels may be provided for internal and external coolant flow. The cold plate may further include compliant ribs, such as U-shaped portions, extending between pillars to absorb stress in the X and Y directions. In a further example, the apparatus may be constructed from copper and may include a thermal interface material layer between one or more semiconductor die or chips and the cold plate, such that the semiconductor die are bonded to the cold plate. In other aspects, the apparatus may be used with multiple chips embedded in a substrate, such that the backside of each chip is exposed or cooling.

The present application claims the benefit of U.S. Provisional Patent Application No. 63/786,488 filed on Apr. 10, 2025, the entire contents of which are incorporated herein by reference.

### BACKGROUND

Electronic systems often utilize various methods to manage temperature during operation. Different types of cooling devices can be employed to control heat in these systems.

### SUMMARY

Some implementations described herein provide a cold plate for semiconductor cooling that incorporates structural compliance to accommodate differential thermal expansion between the cold plate and adjacent semiconductor chips. For example, the apparatus includes a cold plate comprising a first portion with a plurality of thermally conductive portions, such as pillars, wherein the pillars are spaced from one another at their first ends adjacent the chip surface. The cold plate is configured to absorb thermally induced stress in both the X and Y directions parallel to the chip surface, while maintaining rigidity in the Z direction perpendicular to the chip surface. The second ends of the pillars, in one example, merge to form a second portion of the cold plate, facilitating heat transfer away from the chip. In some aspects, the pillars may be solid or hollow. If hollow, channels may be provided for internal and external coolant flow. The cold plate may further include compliant ribs, such as U-shaped portions, extending between pillars to absorb stress in the X and Y directions. In a further example, the apparatus may be constructed from copper and may include a thermal interface material layer between one or more semiconductor die or chips and the cold plate, such that the semiconductor die are bonded to the cold plate. In other aspects, the apparatus may be used with multiple chips embedded in a substrate, such that the backside of each chip is exposed for cooling.

### BRIEF DESCRIPTION OF THE DRAWINGS

The accompanying drawings, which are incorporated in and constitute a part of this specification, illustrate one or more implementations described herein and, together with the description, explain these implementations. In the drawings:

FIG. 1 shows a cross-sectional view of an example of a wafer scale chip package 100 consistent with an aspect of the present disclosure;

FIG. 2 shows a perspective view of an inlet side of a cold plate portion 202 consistent with an aspect of the present disclosure;

FIG. 3 shows a perspective view of an outlet side of a cold plate portion 202 consistent with an aspect of the present disclosure;

FIG. 4 shows a bottom isometric view of a portion of cold plate portion 202 consistent with an aspect of the present disclosure;

FIG. 5 shows a top view of cold plate portion 202 consistent with an aspect of the present disclosure with locations of the cross-sectional planes;

FIG. 6 shows a cross-sectional view of the cold plate portion taken along line 6-6 in FIG. 5 consistent with an aspect of the present disclosure;

FIG. 7 shows a cross-sectional view of the cold plate portion taken along line 7-7 in FIG. 5 consistent with an aspect of the present disclosure;

FIG. 8 shows a cross-sectional view of the cold plate portion taken along line 8-8 in FIG. 5 consistent with an aspect of the present disclosure;

FIG. 9 shows a cross-sectional view of the cold plate portion taken along line 9-9 in FIG. 5 consistent with an aspect of the present disclosure;

FIG. 10 shows a cross-sectional view of the cold plate portion taken along line 10-10 in FIG. 5 consistent with an aspect of the present disclosure;

FIG. 11 shows a perspective view of coolant flow down a pillar within the cold plate portion consistent with an aspect of the present disclosure;

FIG. 12 is a cross-sectional edge view of the cold plate portion illustrating compliant features consistent with an aspect of the present disclosure;

FIG. 13a is a isometric view of a further embodiment illustrating a heat transfer element with segmented pillars sandwiched between a chiplet and a heat sink.

FIG. 13b is an cross-sectional view of the heat transfer element of FIG. 13a, showing the pillars merging into a uniform portion distal to the chiplet.

FIG. 13c is a bottom plane view of the heat transfer element of FIG. 13a, illustrating the array of pillars and the gaps provided to accommodate thermal expansion.

### DETAILED DESCRIPTION

The following detailed description of example implementations refers to the accompanying drawings. The same reference numbers in different drawings may identify the same or similar elements.

High performance computing hardware consumes large amounts of power and requires liquid cooling to remove heat in dense datacenter environments. Conventionally, a cold plate is attached to the CPUs, GPUs, power supplies, and other hot components. Water, or other coolant, is then pumped through the cold plate to remove heat. A typical cold plate contains a base made of solid copper, or other thermally conductive material, inside of which there is an array of closely spaced fins, pillars, or other structures that increase the contact area between the copper and coolant for efficient heat transfer. The base is enclosed in a liquid tight enclosure that includes fittings for coolant delivery. Cold plate performance for a particular application is optimized by balancing coolant temperature, flow rate, pressure drop, thermal resistance, and other factors. The cold plate is typically coupled to the heat source through a thermal interface material (TIM). In one example, the TIM is a thermally conductive adhesive, pad, putty, film, paste, or liquid that is compressed between the heat source and the cold plate to ensure good thermal contact. In another example, the TIM includes a solder alloy, which includes indium, for example. In a further example, such solder sticks to bare silicon with or without a surface activation layer

The compression force is applied by screws, springs, or other mechanical means. Alternatively, some TIM materials can act as a bonding interface to bond the cold plate to the chips so that the clamping force is not needed in operation. Variations in the flatness of the mating components, TIM thickness, applied compression force, movement, or aging can increase thermal resistance and impair cooling performance.

One conventional approach for in-chip cooling involves providing grooves or other structures in the back surface of a silicon chip, such that coolant is flowed directly over the chip to thereby cool the chip.

Another conventional approach involves direct impingement cooling whereby coolant is directed onto the back of the silicon chip from an array of fluid ports arranged in parallel.

Both approaches may have adequate cooling performance, but, because the coolant directly contacts the silicon chip, a fluid seal may be required along the periphery of the chip surface and may be formed using a gasket, O-ring, or adhesive, for example. However, if the seal is damaged or broken, the coolant may leak, potentially damaging the semiconductor chip and causing the circuits thereon to fail. Additionally, the periphery of the chip surface, upon which the seal is provided, is not exposed to coolant, and, therefore, is not cooled. Moreover, these approaches are typically limited to cooling individual chips. Advanced packages including multiple chips have surface discontinuities between the chips that can impair seal reliability, which may render conventional cooling techniques unsuitable for such multi-chip packages.

The construction of conventional liquid cooling solution requires that the cold plates, often made of copper, be attached to the silicon chip with a TIM and mechanical clamped or bonded in such a way to tolerate differential thermal expansion of the silicon chip and the cold plate base. Such differential expansion rate (CTE mismatch) is caused by the different coefficient of thermal expansion of the two materials, e.g., copper and silicon. For small chips, the dimensional difference caused by the CTE mismatch does not result in a significant difference in the amount of expansion. That is, since the chips, in this instance have a relatively small length and width, the amount that such chips expand or contract in response to changes in temperature is minimal. Advanced semiconductor packages, however, include multiple chips that collectively have a relatively large length and width and are often embedded in a substrate. The resulting CTE mismatch associated with a relatively large cold plate attached to such a package, therefore, increases stress on the chips and may cause the chip package to warp or delaminate from the cold plate. Wafer scale chip packages are the size of a 300 mm diameter wafer, in one example, which, in this instance, may require the TIM to accommodate a shear displacement greater than 100 microns at the periphery package when heated to temperatures typical of operating semiconductor chips.

Some implementations described herein provide a cold plate for semiconductor cooling that incorporates structural compliance to accommodate differential thermal expansion between the cold plate and adjacent semiconductor chips. For example, the apparatus includes a cold plate comprising a first portion with a plurality of thermally conductive portions, such as pillars, wherein the pillars are spaced from one another at their first ends adjacent the chip surface. The cold plate is configured to absorb thermally induced stress in both the X and Y directions parallel to the chip surface, while maintaining rigidity in the Z direction perpendicular to the chip surface. The second ends of the pillars, in one example, merge to form a second portion of the cold plate, facilitating heat transfer away from the chip. In some aspects, the pillars may be solid or hollow. If hollow, channels may be provided for internal and external coolant flow. The cold plate may further include compliant ribs, such as U-shaped portions, extending between pillars to absorb stress in the X and Y directions. In a further example, the apparatus may be constructed from copper and may include a thermal interface material layer between one or more semiconductor die or chips and the cold plate, such that the semiconductor die are bonded to the cold plate. In other aspects, the apparatus may be used with multiple chips embedded in a substrate, such that the backside of each chip is exposed for cooling.

Consistent with further aspects of the present disclosure, the cold plate structure enables lateral compliance, allowing expansion and contraction in response to thermal loads without inducing excessive stress or warpage in large, multi-chip or wafer-scale semiconductor packages. Portions of the cold plate including compliant features, such as spaced pillars and flexible ribs, mitigate the effects of coefficient of thermal expansion mismatch, reducing the risk of chip cracking or weakening of electrical connections and delamination at the TIM interface. A parallel coolant flow through internal and external channels, in one example, ensures uniform cooling of the die and maintains low pressure drop across the cold plate. As a result, the apparatus consistent with the present disclosure provides a stable, low-resistance thermal interface that maintains flatness and structural integrity during operation, eliminates the need for mechanical clamping, and addresses technical challenges associated with cooling efficiency, reliability, and scalability in advanced multi-chip packages.

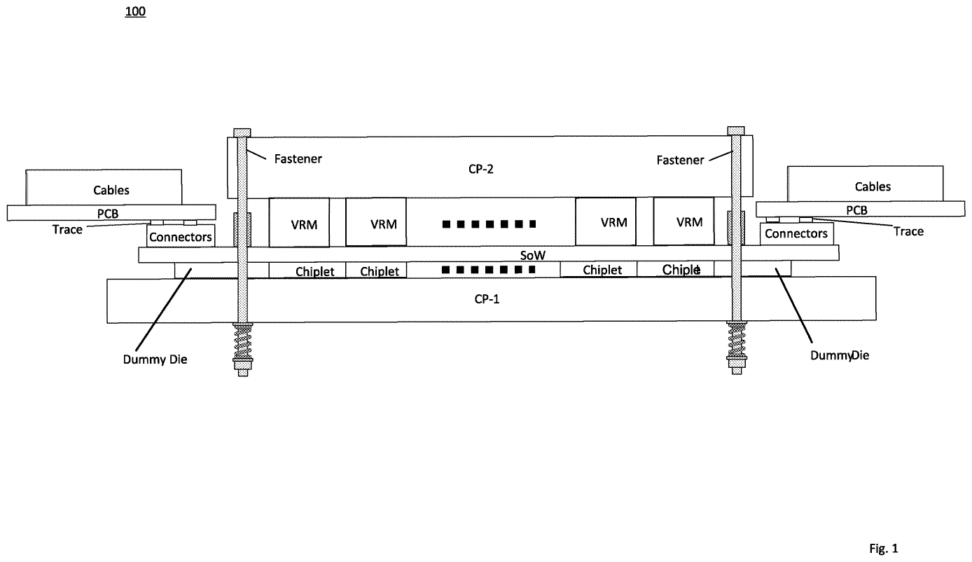

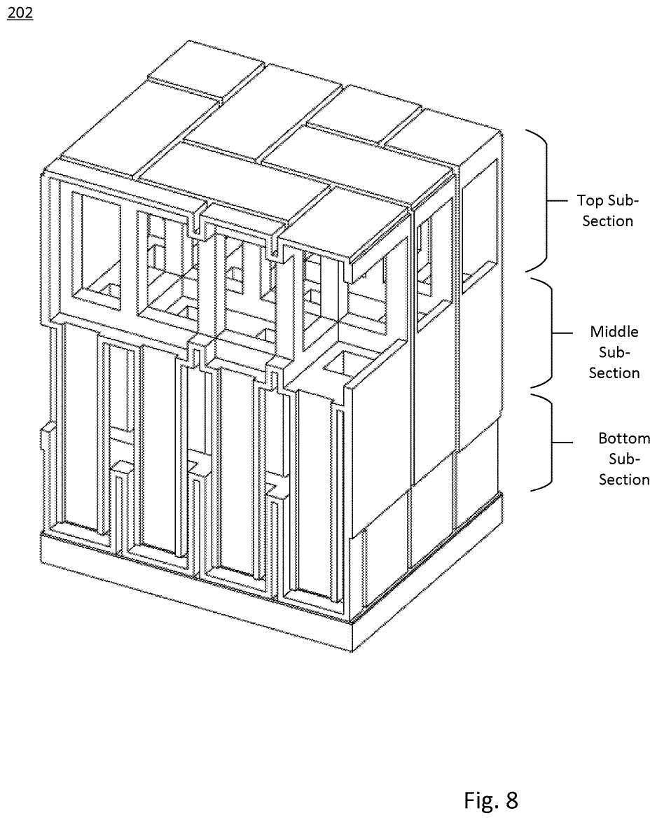

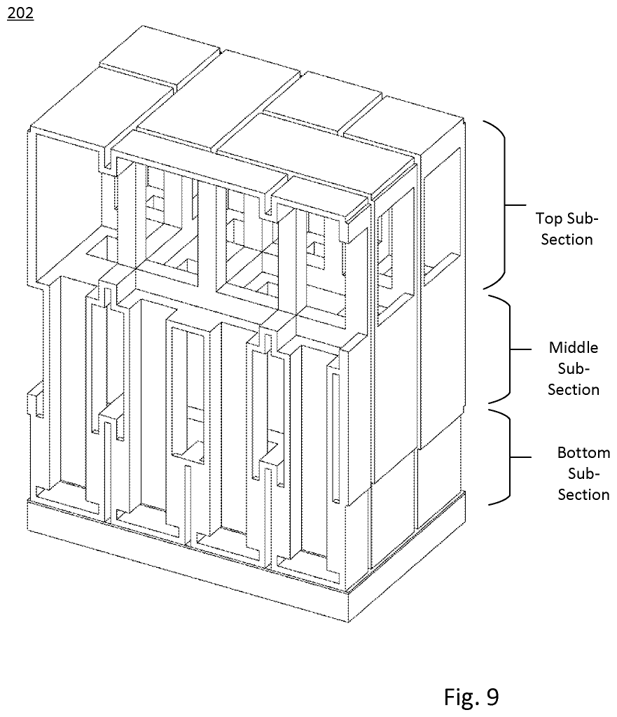

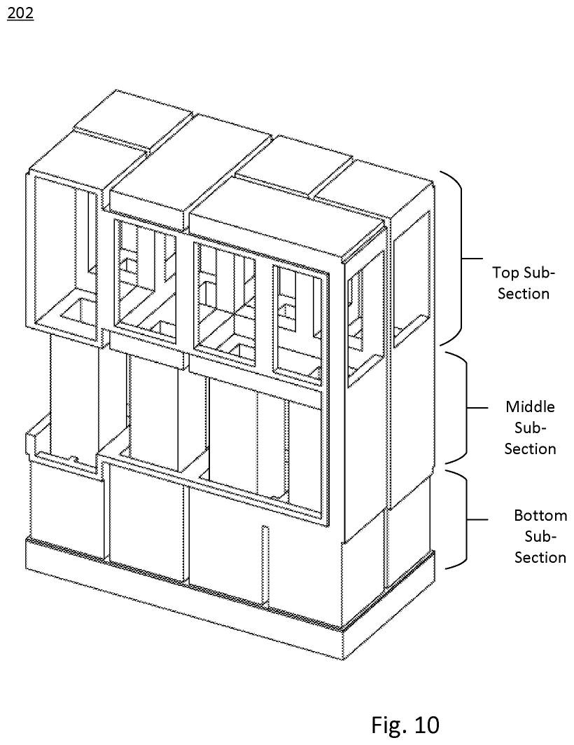

A cold plate consistent with an aspect of the present disclosure will next be described with reference to FIGS. 1-12.

FIG. 1 shows a cross-sectional view of an example of a wafer scale chip package 100 consistent with an aspect of the present disclosure. Package 100 include a plurality of chiplets or die provided on a first cold plate CP-1. A TIM, not shown, may be provided between the chiplets and cold plate CP-1. The chiplets are also embedded or attached to a System on Wafer (SoW), which may include a resin material in which electrical conductors are provided that connect to the chiplets and provide electrical signals to and transmit electrical signals from the chiplets. Electrical signals output from package 100 may be supplied to electrical connectors, for example, that direct the signals to traces included in a printed circuit board (PCB). Electrical cables coupled or connected to the PCB traces, in turn, output the electrical signals from package 100.

As further shown in FIG. 1, voltage regulator modules (VRMs) are provided that supply a desired current and voltage to the chiplets to facilitate operation of the integrated circuits provided on each chiplet. An additional cold plate CP-2 is provided to regulate or cool the VRMs. Fasteners, such as screws, are provided to maintain structural integrity of package 100, as well as electrical and/or thermal contact between the elements shown in FIG. 1.

As noted above, CTE mismatch between the cold plate, e.g., cold plate CP-1, and the chiplets included in the SoW can create shear forces on the chiplets and cause the SoW to warp. Under some circumstances the chiplets may crack or electrical connects to the chiplets may then weaken or break as a result of such shear forces.

Consistent with the present disclosure, however, cold plate CP-1, rather than being a rigid structure, includes portions having compliant features that allow the cold plate to flexibly expand and contract at a rate that matches the silicon chips and package, as described in greater detail below. This allows the cold plate to be bonded to a wafer scale chip package, including chiplets embedded in an SoW, with a thermally conductive adhesive or solder without creating excessive stress and warpage when heated to operating temperature. As a result, a stable, high performance thermal interface may be achieved without the need for additional mechanical structures, such as screws or springs, which are otherwise required to clamp the assembly together and hold it flat.

The cold plate structure described herein and illustrated below represents one possible embodiment of this concept, but other examples are contemplated herein. The design includes different elements which together create the desired compliance and coolant flow characteristics of the cold plate. In each instance, different features or dimensions may be employed consistent with the present disclosure.

In one example, cold plate CP-1, is formed as a piece of copper using Electrochemical Additive Manufacturing (ECAM). Other techniques employing 3D printing may also be employed. If ECAM is employed, internal cavities and features may be created without the need for support material during fabrication. Accordingly, fluid channels, manifolds, ribs, columns, fins, stress relief structures, for example, may be readily formed. In another example, such features may be created with other fabrication processes including powder bed fusion. Preferably, the process employed to make cold plate CP-1 creates an enclosed volume that reliably contains the liquid coolant without potential leak points.

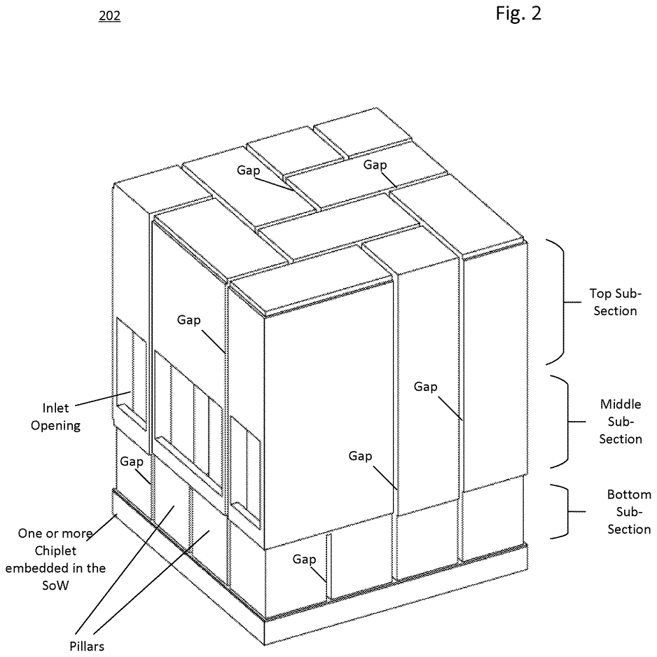

Consistent with a further aspect of the present disclosure, cold plate CP-1 includes a plurality of sections that, collectively, extend across the entire SoW. An example of one such section is shown in FIG. 2 as cold plate section 202, which includes three sub-sections, a bottom sub-section, a middle sub-section, and a top sub-section, provided in a vertical stack. The bottom sub-section or layer, which cools the underlying chiplets, includes portions, such as a rectangular array of vertical pillars separated by narrow air gaps. In each of the examples shown in FIGS. 1-12, the bottom sub-section of the cold plate may be bonded to the chiplet with a TIM. Examples of TIMs are discussed above. Coolant may be provided through inlet openings, which may be configured and located in such a manner to provide sufficient coolant to cold plate section 202. In one example, the inlet openings are provided on one side of cold plate section 202, as shown in FIG. 2. Alternatively, in another example, coolant inlet openings are provided in the top sub-section of cold plate section 202.

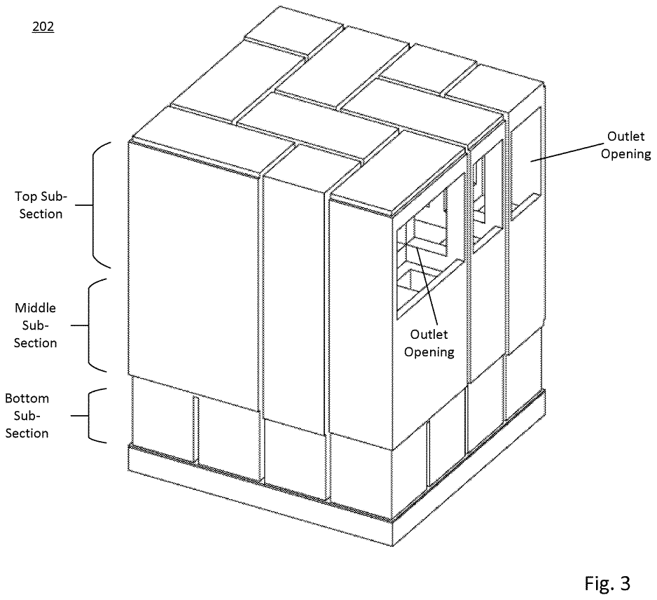

After circulating in cold plate section 202 and absorbing heat from the chiplets, the coolant may next be output through outlet openings, which may be configured and located in such a manner to adequately exhaust heated coolant from cold plate section 202. In one example, the outlet openings are provided on a side of cold plate section 202 opposite the side where the inlet openings are provided, as shown in FIG. 3. In a further example, the outlet openings are provided in the top section of cold plate section 202.

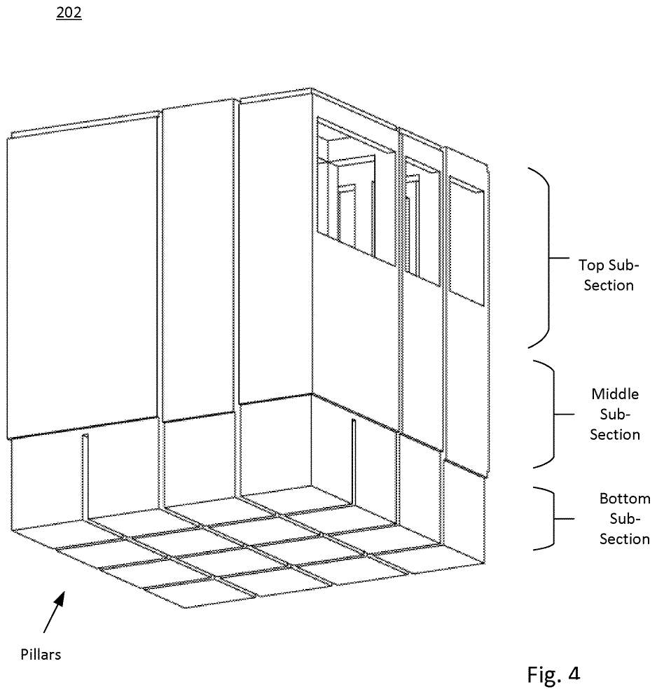

FIG. 4 shows a bottom isometric view of a portion of cold plate section 202, further illustrating the pillars.

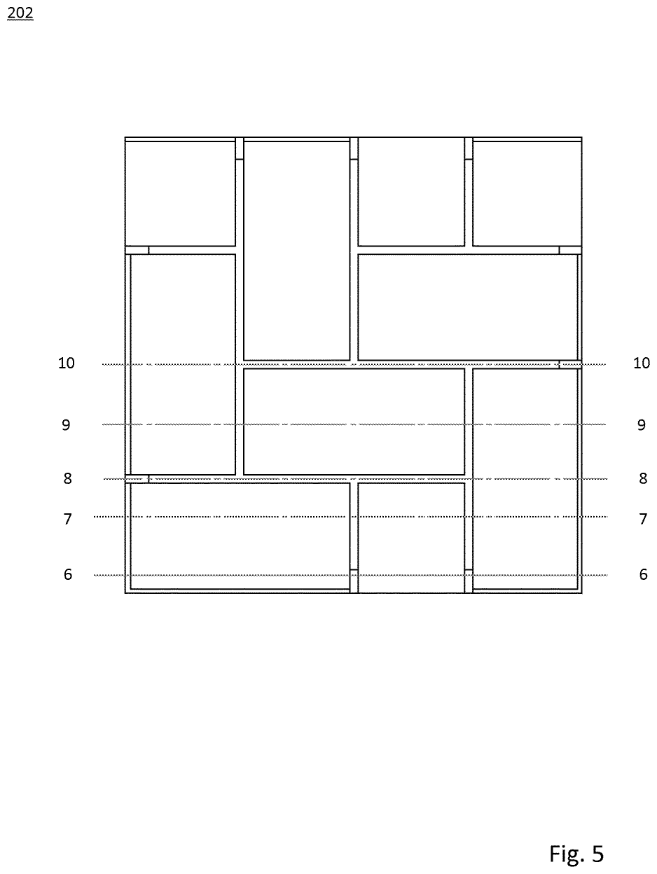

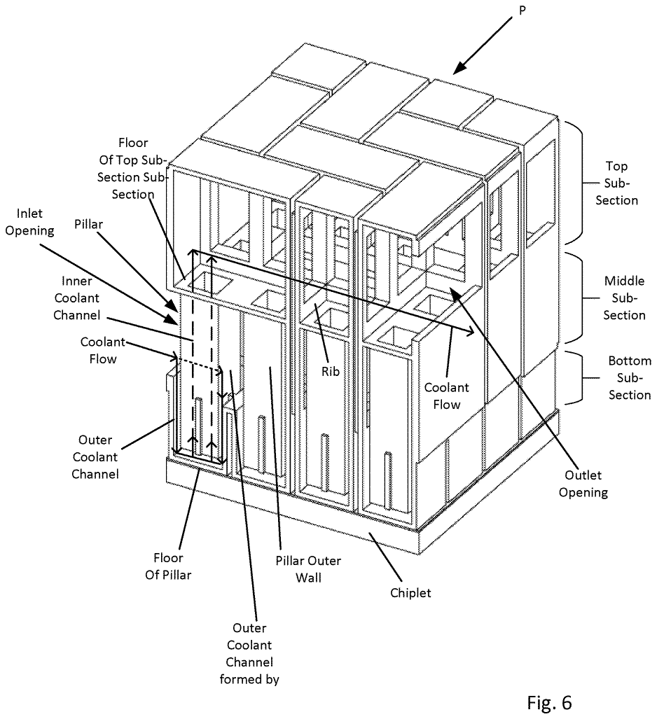

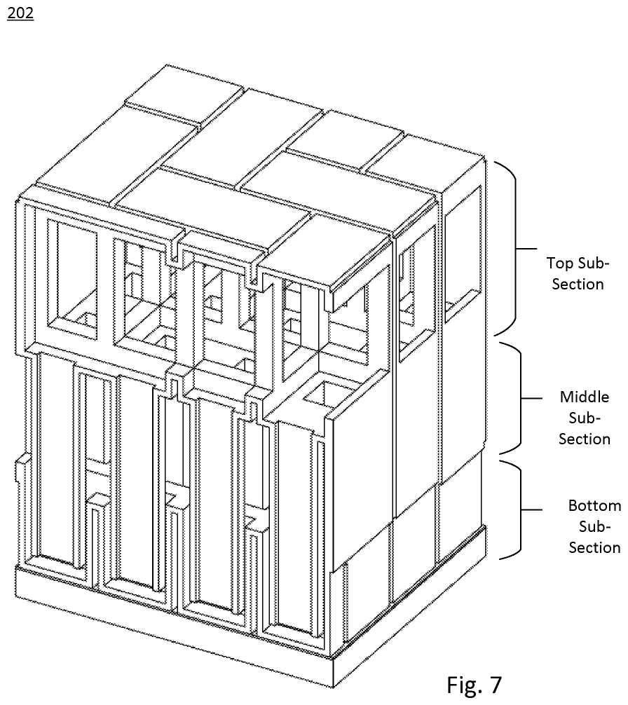

FIG. 5 shows a top view of cold plate section 202. FIG. 6 shows a cross-sectional view taken along line 6-6 in FIG. 5. Further, FIGS. 7-10 show cross-sectional views of cold plate section 202 taken along lines 6-6, 7-7, 8-8, 9-9, and 10-10, respectively, in FIG. 5.

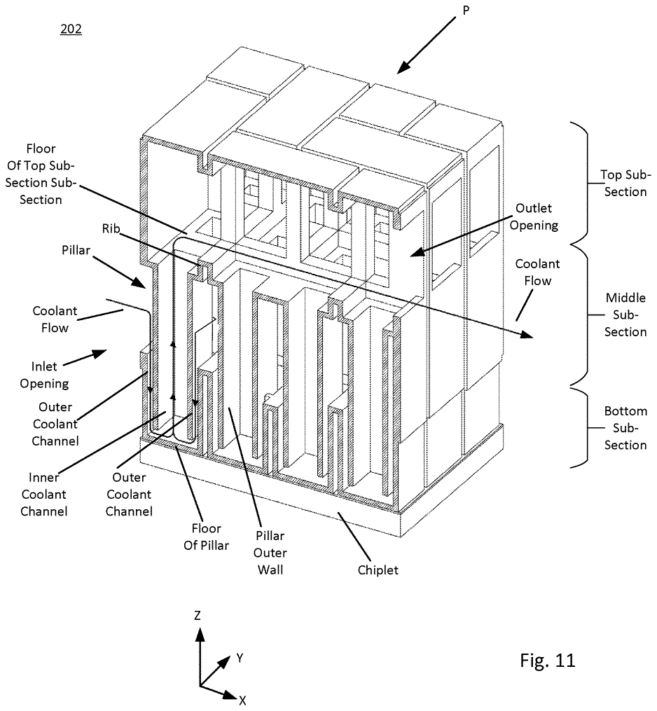

FIGS. 6 and 11 show an example coolant flow through part of cold plate section 202. As shown in FIGS. 6 and 11, coolant enters cold plate section 202 though an inlet opening. As described in greater detail below, the coolant surrounds and flows down the outer walls of each of the pillars, i.e., through an outer channel, to a bottom surface of cold plate section 202 adjacent the chiplet. FIGS. 6 and 11 show coolant flowing down an outer channel of one such pillar. Upon reaching and contacting the bottom surface, the coolant absorbs heat generated by the chiplet and the force or displacement caused by a continuous flow of coolant through the inlet opening causes the coolant to flow up through the central hollow portion or inner channel of each pillar, through the middle sub-section, to the top layer or sub-section of cold plate section 202. The coolant flow next exits cold plate section 202 through outlet openings.

As noted above, each pillar, in one example, has a hollow portion that constitutes an inner coolant channel that extends from the just above the floor of the pillar (adjacent the chiplet), up through the middle of the pillar, and through the middle layer or sub-section of cold plate section 202 to the floor of the top layer of subsection where it opens into the top layer. As further shown in FIGS. 6 and 11, the inner coolant channel is connected to the outer walls of the pillar with support ribs (“ribs”) that position the inner channel coaxially in the pillar. The inlet opening in the middle layer or sub-section, which constitutes a cold manifold, supplies coolant to the pillar array. The middle layer is an open structure, in one example, that allows lateral coolant flow and is connected to the outer coolant channels that surround the inner coolant channel of each pillar. The top layer, which constitutes a “hot” manifold carrying coolant which has been warmed by the chiplets, is located above the cold manifold. The “hot” manifold is also an open structure that allows lateral coolant flow and is connected to the inner coolant channel in each pillar. The outlet opening is provided in the top sub-section of the “hot” manifold. The “cold” and “hot” manifold layers each have one or more fluid ports that connect the cold plate to the external coolant distribution system through the inlet and outlet openings shown in FIGS. 6 and 11.

Together the internal manifold layers and the coolant channels in the pillars of cold plate section 202 include an independent coolant loop, and all pillars are fed cold coolant in parallel from the coolant inlet opening to the cold manifold layer and exhaust heated coolant in parallel to the hot manifold layer and out through the outlet openings. In one example, such parallel coolant flow ensures that all pillars have similar cooling performance. Accordingly, the overall coolant pressure drop remains low in a further example.

As used herein “cold” and “hot” refer to relative temperatures between portions of cold plate section 202, wherein portions characterized as being “cold” have a temperature that is less than portions that are characterized as being “hot”. Alternatively, coolant flow can be in the opposite direction if desired, reversing the role of the cold and hot manifold layers.

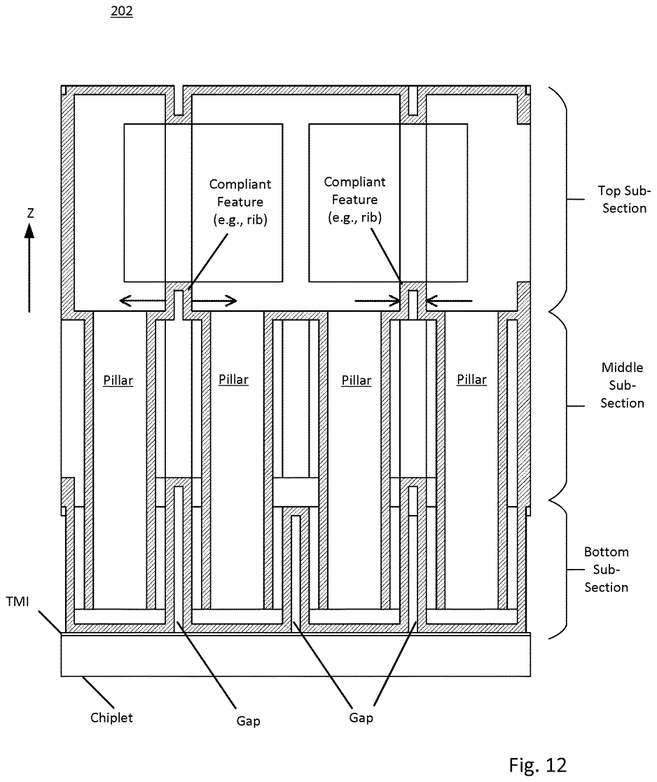

In addition to the parallel coolant flow, the cold plate contains features that allow the cold plate to compliantly expand and contract with the bonded wafer scale chip package without introducing stress and warpage. As shown in the cross-sectional edge view of FIG. 12, the pillars are separated by air gaps that allow the bottom of each pillar to move independently from adjacent pillars. In one example, the cold middle manifold layer (sub-section) and hot upper manifold layer (sub-section) are defined and bounded by three horizontal copper sheets that include structural elements that can deform as the cold plate expands and contracts. As shown in FIG. 12, these compliant features including, in this example, slotted ribs that have a U shaped cross section. This shape allows the slots to function as expansion joints that can absorb changes in the spacing of the pillars without creating excessive stress, as indicated by the arrows shown in FIG. 12. These compliant structures are arranged in a manner that allow compliance on both the X and Y axis while maintaining structural support or rigidity in the Z axis. Put another way, cold plate section 202 is thus configured to absorb thermally induced stress in a first (X direction) and a second (Y) direction extending parallel to a surface of the semiconductor chip or chiplet, wherein cold plate section 202 is more compliant in the first and second directions than in a third (Z) direction perpendicular to the surface of the semiconductor chip or chiplet. The X, Y, and Z directions are shown in FIG. 11, and the Z direction is also shown in FIG. 12. In one example, each slotted rib, in one example, is compliant in one axis while the other two axes remain rigid. To achieve simultaneous compliance in both the X and Y axis, the compliant features are arranged in a way that does not create solid beams that extend more than a relatively short distance. In one example, this is accomplished by grouping the pillars into 2 unit cells. This 2 unit cell is surrounded by compliant slotted ribs on all 4 sides. These 2 unit cells are then arranged in a herringbone tiling pattern P shown in FIGS. 6 and 11 that spans the entire cold plate, which, in one example, includes multiple sections 202. This pattern ensures that all ribs are three pillar units long, and end in a “T” junction that allows compliance in the orthogonal direction. This tiled structure is repeated in each of the three horizontal sheets, allowing the entire structure to flexibly expand and contract along with the wafer scale chip package.

In a further example, the tiled structure and parallel coolant flow described herein allows the cold plate to be subdivided into smaller sections, i.e., multiple sections similar to section 202, that can be placed adjacent one another without creating a cooling performance discontinuity at the junctions. Accordingly, smaller cold plates may be assembled to abut one another or be provided close to one another with narrow gaps therebetween, such that the resulting assembly operates as one large cold plate. Thus, a fabrication process capable of manufacturing such smaller cold plates may be employed to provide a cold plate assembly that functions as a larger unitary cold plate. Each smaller cold plate may have independent coolant ports, such that multiple coolant circulation loops are provided, each associated with a corresponding cold plate of the assembly. In another example, the smaller cold plate portions, such as section 202, may have openings or other features that permit coolant to flow from one such cold plate to another adjacent cold plate.

At the system level, the cold plate may be bonded to the pillar array using adhesive or solder with high thermal conductivity. Maintaining a consistent, thin bond line ensures low thermal resistance between the hot chips and the cold plate. This bonded structure then serves as a stable, flat base for the attachment of other system elements to the wafer scale chip package without concern for warpage or fragility.

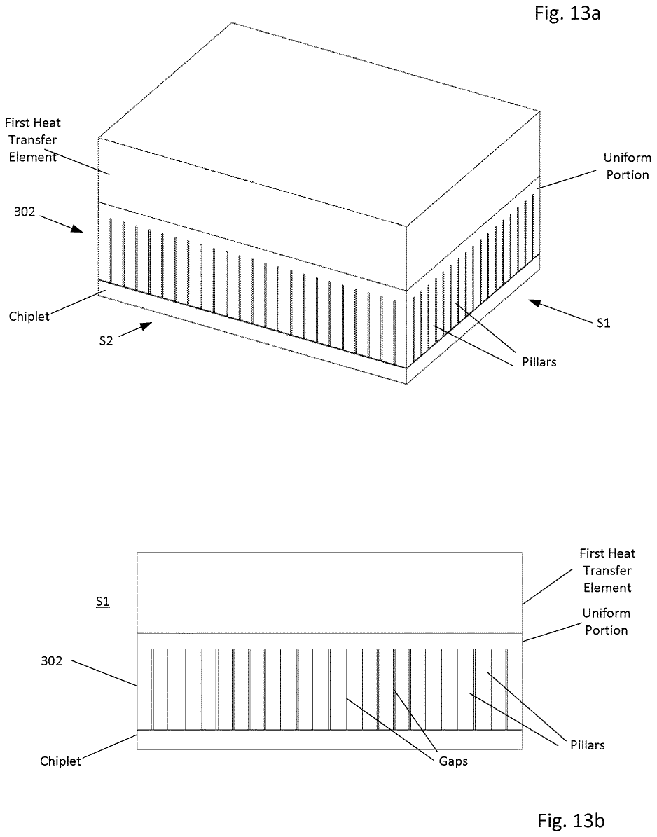

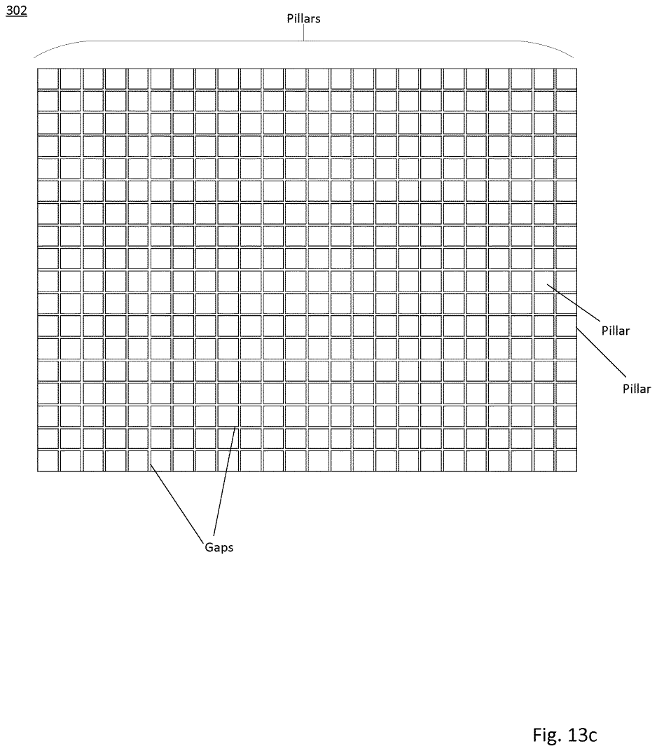

A further embodiment will next be described with reference to FIGS. 13a to 13c. As shown in FIG. 13a, a novel cold plate includes a first heat transfer element, such as a heat sink or conventional cold plate, may be made of copper, for example, and a second heat transfer element 302 or a pillar array. The second heat transfer element is sandwiched between the first heat transfer element and one or more chiplets. Moreover, the second heat transfer element 302 may be bonded to the chiplet with a TIM, as noted above. Accordingly, the TIM may be provided between the second heat transfer element 302 and the chiplet to facilitate sufficient heat transfer from the chiplet to the first heat transfer element. As further shown in FIGS. 13a and 13b, second heat transfer element 302 includes an array of pillars, each of which being separated by a gap that extends from an end of each pillar adjacent the chiplet toward the first heat transfer element or heat sink. At the end of each pillar near the first heat transfer element or heat sink, however, the pillars merge into one another to thereby constitute a uniform or integral portion. With this construction, heat generated by the chiplet, which may be made of silicon, for example, may cause some movement of the pillar end near the chiplet. Such movement is minor, however, because the dimensions of the pillar, such as the width, at the pillar ends adjacent the chiplet are relatively small. Accordingly, any movement of such pillar ends due to coefficient of thermal expansion (CTE) mismatch of the pillars and chiplet is insufficient to cause damage to the chiplet or the TIM interface. On the other hand, if the cold plate constitutes a large continuous block without pillars and gaps therebetween, the cold plate may expand significantly, especially at the edges of the cold plate, and thus may damage the chiplet or the TIM interface.

FIG. 13c, shows a bottom plane view of heat transfer element 302 including an array of pillars, wherein each pillar of the array is separated from one another by a gap, as noted above.

The foregoing disclosure provides illustration and description, but is not intended to be exhaustive or to limit the implementations to the precise forms disclosed. Modifications may be made in light of the above disclosure or may be acquired from practice of the implementations.

Although particular combinations of features are recited in the claims and/or disclosed in the specification, these combinations are not intended to limit the disclosure of various implementations. In fact, many of these features may be combined in ways not specifically recited in the claims and/or disclosed in the specification. Although each dependent claim listed below may directly depend on only one claim, the disclosure of various implementations includes each dependent claim in combination with every other claim in the claim set. As used herein, a phrase referring to “at least one of” a list of items refers to any combination of those items, including single members. As an example, “at least one of: a, b, or c” is intended to cover a, b, c, a-b, a-c, b-c, and a-b-c, as well as any combination with multiple of the same item.

No element, act, or instruction used herein should be construed as critical or essential unless explicitly described as such. Also, as used herein, the articles “a” and “an” are intended to include one or more items, and may be used interchangeably with “one or more.” Further, as used herein, the article “the” is intended to include one or more items referenced in connection with the article “the” and may be used interchangeably with “the one or more.” Furthermore, as used herein, the term “set” is intended to include one or more items (e.g., related items, unrelated items, or a combination of related and unrelated items), and may be used interchangeably with “one or more.” Where only one item is intended, the phrase “only one” or similar language is used. Also, as used herein, the terms “has,” “have,” “having,” or the like are intended to be open-ended terms. Further, the phrase “based on” is intended to mean “based, at least in part, on” unless explicitly stated otherwise. Also, as used herein, the term “or” is intended to be inclusive when used in a series and may be used interchangeably with “and/or,” unless explicitly stated otherwise (e.g., if used in combination with “either” or “only one of”).

1. An apparatus, comprising:
a plurality of cooling loops, each of which extending parallel to one another, each of the plurality of cooling loops including a first channel and a second channel, such that a liquid coolant flows in the first channel in a first flow direction toward a semiconductor chip, and the liquid coolant flows in the second channel in a second flow direction away from the semiconductor chip;
a first plurality of compliant ribs, each of which being associated with a respective one of the plurality of cooling loops, each of the first plurality of compliant ribs being operable to flex in response to a first thermally induced stress caused by heat generated by the heat source applied in a first stress direction; and
a second plurality of compliant ribs, each of which being associated with a respective one of the plurality of cooling loops, each of the second plurality of expansion joints being operable to flex in response to a second thermally induced stress applied in a second stress direction.

2. An apparatus in accordance with claim 1, wherein each of the plurality of cooling loops includes a corresponding one of a plurality of pillars.

3. An apparatus in accordance with claim 2, wherein the first channel of each of the plurality of cooling loops is included in a corresponding one of the plurality of pillars.

4. An apparatus in accordance with claim 2, wherein one of the first plurality of compliant ribs extends between adjacent first and second ones of the plurality of pillars.

5. An apparatus in accordance with claim 4, wherein said one of the first plurality of compliant ribs includes a first arm extending to the first one of the plurality of pillars and a second arm extending to the second one of the plurality of pillars.

6. An apparatus in accordance with claim 5, wherein said one of the first plurality of compliant ribs includes a U-shaped portion provided between the first and second arms.

7. An apparatus in accordance with claim 4, wherein said one of the first plurality of compliant ribs extends in the second direction and terminates to thereby absorb the thermally induced stress in the second stress direction.

8. An apparatus in accordance with claim 1, wherein the semiconductor chip is one of a plurality of semiconductor chips.

9. An apparatus in accordance with claim 1, further including a layer including a thermal interface material provided between the semiconductor chip and the plurality of cooling loops.

10. An apparatus in accordance with 1, further including a substrate, the semiconductor chip being embedded in the substrate, such that a backside of the semiconductor chip is exposed and constitutes the surface of the semiconductor chip.

11. An apparatus in accordance with claim 10, wherein the substrate includes a resin and conductors included in the resin that connect to the circuitry on the semiconductor chip.

12. An apparatus in accordance with claim 11, wherein the semiconductor chip is one of a plurality of semiconductor chips, which are embedded in the resin, such that a backside of the plurality of chips is exposed.
